(19) United States
(12) Patent Application Publication
(10) Pub. No.: US 2007/0070672 A1
(43) Pub. Date: Mar. 29, 2007

(54) Semiconductor device and driving method thereof

(75) Inventor: Young-Do Hur, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/540,982

(22) Filed: Sep. 28, 2006

(30) Foreign Application Priority Data
Sep. 29, 2005 (KR) 2005-0090912
May 31, 2006 (KR) 2006-0049115

(51) Int. Cl. G11C 7/02

(52) U.S. Cl. 365/53

(57) ABSTRACT

A semiconductor device includes a first internal voltage generator generating an internal voltage using a first external power supply voltage in a normal mode; a second internal voltage generator generating the internal voltage using a second external power supply voltage supplied through a no connection (N/C) pin in a test mode; an internal operation circuit performing a target operation with the internal voltage generated at one of the first internal voltage generator and the second internal voltage generator; and a data output buffer outputting an output data in response to the target operation by the internal operation circuit through a data input/output pad in one of the normal mode and the test mode.

### FIELD OF THE INVENTION

The present invention relates to a semiconductor technology, and more particularly, to a semiconductor technology for internal voltages of a semiconductor device.

### DESCRIPTION OF RELATED ARTS

Generally, semiconductor memory devices are capable of supplying voltages necessary for operating internal circuits of a chip by installing internal voltage generators within the chip to generate internal voltages using a power supply voltage supplied from an external source. Particularly, dynamic random access memories (DRAMs) operate using those internal voltages such as a high voltage (VPP), a core voltage (VCORE) and a cell plate voltage (VCP).

For a test mode for testing an operation state of a device using the aforementioned internal voltages, an external test device supplies an internal voltage through a specific pin during the test mode.

FIG. 1 illustrates a block diagram of a typical semiconductor device.

Particularly, FIG. 1 illustrates a circuit related to a high voltage VPP, a circuit related to a core voltage VCORE, and a circuit related to a cell plate voltage VCP. Since these circuits have a similar configuration, the circuit related to the high voltage VPP will be described in detail herein below.

The high voltage VPP related circuit includes a data input/output pad 10 (hereinafter referred to as “DQ pad”), a VPP generator 20, a VPP operation circuit 30, and a data buffer 40. The VPP generator 20 generates a high voltage VPP using an external power supply voltage VDD and a ground voltage VSS. The VPP generator 20 is controlled by a VPP enable signal VPPEN using a separate reference signal VREFP. The VPP operation circuit 30 is an internal operation circuit that performs various operations after being supplied with the high voltage VPP provided from the VPP generator 20. For instance, a sub-word line driver and a bit line equalizing signal generator, both using the high voltage VPP correspond to the internal operation circuit.

A multiplexer 50 selectively makes a connection between the DQ pad 10 and one of the data buffer 40 and a high voltage VPP terminal in response to a selection signal SELECT_VPP. In a normal mode, the VPP enable signal VPPEN is in a logic high state, and thus, the VPP generator 20 operates. At the same time, the selection signal SELECT_VPP is in a logic low state, and thus, the multiplexer 50 makes an electric connection between the DQ pad 10 and the data buffer 40. In more detail, the high voltage VPP generated by the VPP generator 20 is supplied to the VPP operation circuit 30 to execute all operations of the semiconductor device using the high voltage VPP, and data that are outputted due to the execution of the entire operations are provided to the DQ pad 10 through the data buffer 40.

In a test mode, the VPP enable signal VPPEN is in a logic low state, and thus, the VPP generator 20 does not operate. In contrast, the selection signal SELECT_VPP is in a logic high state, and thus, the multiplexer 50 makes an electric connection between the DQ pad 10 and the VPP operation circuit 30. That is, the high voltage VPP is supplied externally through the DQ pad 10. The VPP operation circuit 30 executes necessary operations using the externally supplied high voltage VPP. Data that are outputted due to the execution of the necessary operations often are not provided to the DQ pad 10 through the data buffer 40 to check an erroneous operation. Thus, data may not be checked during the test mode.

Since the core voltage VCORE related circuit and the cell plate voltage VCP related circuit have the similar configuration to the high voltage VPP related circuit, the core voltage VCORE related circuit and the cell plate voltage VCP related circuit operate similarly during the normal mode and the test mode.

In the typical semiconductor device, the test mode is generally executed by supplying the internal voltage through the DQ pad to check the internal operation circuit that executes necessary operations after being supplied with the internal voltage. In this case, however, a portion of the DQ pad is used to receive the internal voltage during the test mode. Thus, data may not be inputted or outputted through a corresponding portion of the DQ pad. Accordingly, the test may be executed without receiving the output data corresponding to the portion of the DQ pad. As a result, the test often has a degraded level of reliability. Also, as the number of the DQ pads that are used to supply internal voltages increases, the test reliability is likely to be degraded.

### SUMMARY OF THE INVENTION

It is, therefore, an object of the present invention to provide a semiconductor device that can improve reliability of a test for checking an internal operation circuit that executes necessary operations after being supplied with an internal voltage and a driving method thereof.

In accordance with an aspect of the present invention, there is provided a semiconductor device, including: a first internal voltage generator generating an internal voltage using a first external power supply voltage in a normal mode; a second internal voltage generator generating the internal voltage using a second external power supply voltage supplied through a no connection (N/C) pin in a test mode; an internal operation circuit performing a target operation with the internal voltage generated at one of the first internal voltage generator and the second internal voltage generator; and a data output buffer outputting an output data in response to the target operation by the internal operation circuit through a data input/output pad in one of the normal mode and the test mode.

In accordance with another aspect of the present invention, there is provided a driving method of a semiconductor device, the driving method including: generating an internal voltage using a first external power supply voltage in a normal mode; generating the internal voltage using a second external power supply voltage supplied through an N/C pin in a test mode; performing a target operation after receiving the internal voltage; and outputting an output data through a data input/output pad in one of the normal mode and the test mode.

### BRIEF DESCRIPTION OF THE DRAWINGS

The above and other objects and features of the present invention will become better understood with respect to the following description of the exemplary embodiments given in conjunction with the accompanying drawings, in which:

FIG. 1 illustrates a block diagram of a typical semiconductor device;

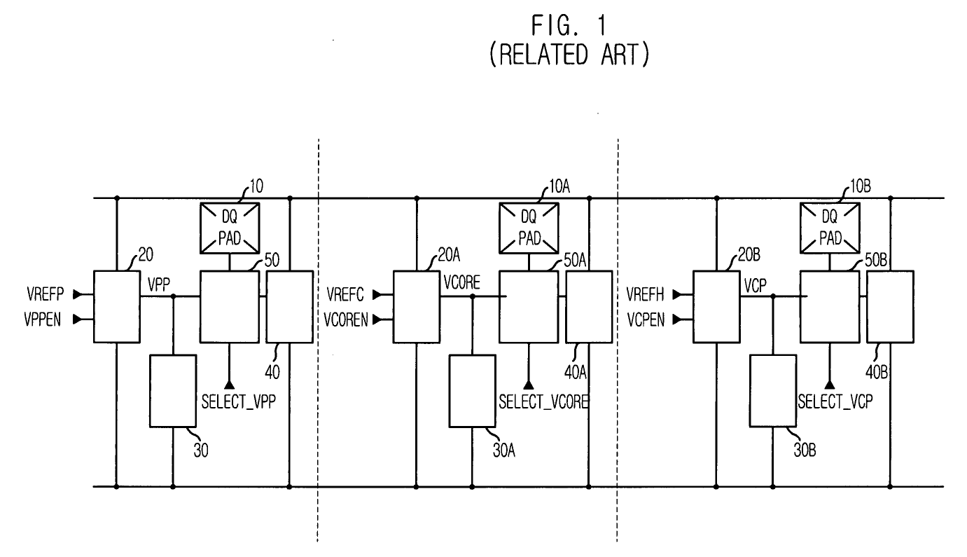

FIG. 2 illustrates a simplified block diagram of a semiconductor device in accordance with an embodiment of the preset invention; and

FIG. 3 illustrates a simplified circuit diagram of a second internal voltage generator illustrated in FIG. 2.

### DETAILED DESCRIPTION OF THE INVENTION

A semiconductor device and a driving method thereof in accordance with various embodiments of the present invention will be described in detail with reference to the accompanying drawings.

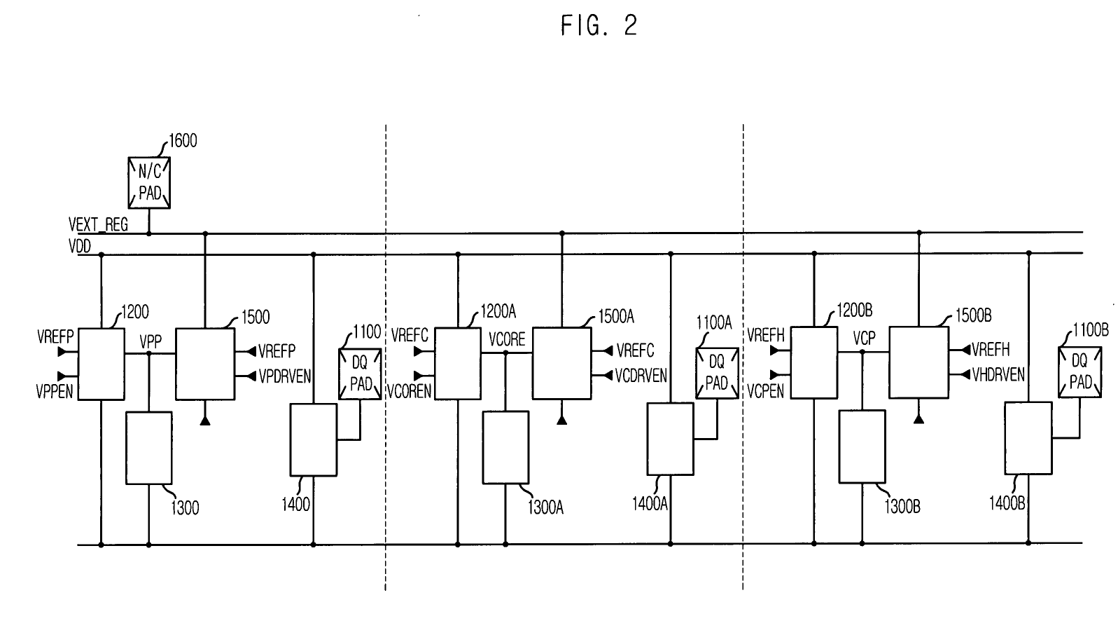

FIG. 2 illustrates a simplified block diagram of a semiconductor device in accordance with an embodiment of the present invention.

When a high voltage VPP is supplied from an external source to test a VPP operation circuit, one no connection (N/C) pin is used. That is, a test external power supply voltage VEXT_REG is applied through one of the N/C pins to generate internal voltages including a high voltage VPP, a core voltage VCORE, and a cell plate voltage VCP. The test external power supply voltage VEXT_REG is a high voltage that is supplied from the external source through the N/C pin during a test mode. In particular, the test external power supply voltage VEXT_REG has a voltage level greater than the high voltage VPP.

Herein below, a method for supplying the high voltage VPP to a VPP operation circuit 1300 will be described in detail. Other internal voltage operation circuits including a VCORE operation circuit 1300A and a VCP operation circuit 1300B are applied identically with the method for supplying the high voltage VPP to the VPP operation circuit 1300.

In a normal mode, a first enable signal VPPEN is activated to a logic high state, and thus, a first VPP generator 1200 operates. On the other hand, a second enable signal VPDRVEN is inactivated to a logic low state, and thus, a second VPP generator 1500 does not operate.

The first VPP generator 1200 operates after being supplied with an external power supply voltage VDD and, outputs the high voltage VPP in response to a reference voltage VREFP, which is set to a certain level inside the semiconductor device. The high voltage VPP generated at the first VPP generator 1200 is supplied to the VPP operation circuit 1300 to make the VPP operation circuit 1300 operate. An output data obtained after the operation of the VPP operation circuit 1300 is inputted to a DQ pad 1100 through a data buffer 1400.

A test external power supply voltage VEXT_REG that has a greater voltage level than the external power supply voltage VDD is supplied from the outside to an N/C pin 1600 to shift an operation mode from the normal mode to a test mode. The reason for supplying the test external power supply voltage VEXT_REG is that the second VPP generator 1500 operates during the test mode with the test external power supply voltage VEXT_REG. Since the second VPP generator 1500 has a voltage down converter structure, the second VPP generator 1500 uses the test external power supply voltage VEXT_REG as an operation supply voltage to easily generate the high voltage VPP during the test mode. Herein, the high voltage VPP has a greater voltage level than the external power supply voltage VDD.

In the test mode, the first enable signal VPPEN is inactivated to a logic low state, and thus, the first VPP generator 1200 does not operate. On the other hand, the second enable signal VPDRVEN is activated to a logic high state, and thus, the second VPP generator 1500 operates.

The second VPP generator 1500 operates using the test external power supply voltage VEXT_REG that has been supplied through the N/C pin 1600 during the test mode. As similar to the first VPP generator 1200, the second VPP generator 1500 generates the high voltage VPP in response to the reference voltage VREFP. The high voltage VPP generated at the second VPP generator 1500 is supplied to the VPP operation circuit 1300 to make the VPP operation circuit 1300 operate. An output data obtained after the operation of the VPP operation circuit 1300 is inputted to the DQ pad 1100 through the data buffer 1400.

The reference voltage VREFP used to generate the high voltage VPP at the first and second VPP generators 1200 and 1500 is outputted from a static power supply circuit installed inside the semiconductor device. A consistent voltage level of the reference voltage. VREFP is maintained without being affected by changes in other parameters such as process, voltage and temperature.

According to the present embodiment, in the test mode for testing the VPP operation circuit 1300, the test external power supply voltage VEXT_REG is supplied through the N/C pin 1600 to generate the high voltage VPP. Thus, the test external power supply voltage. VEXT_REG is not inputted to the DQ pad 1100. As a result, an error can be checked since data outputted during the test mode are inputted to the DQ pad 1100.

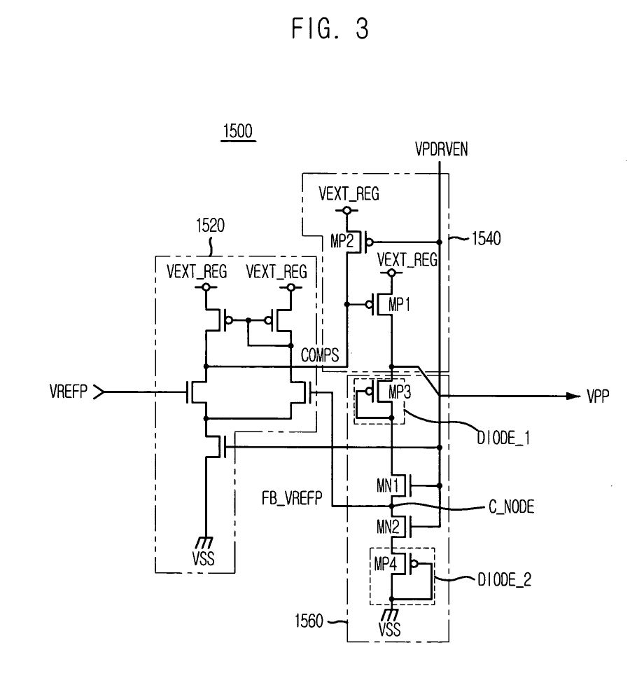

FIG. 3 illustrates a simplified circuit diagram of an internal voltage generator in accordance with an embodiment of the present invention. Particularly, the second VPP generator 1500 illustrated in FIG. 2 is exemplified as the internal voltage generator. Herein below, like reference letters or numerals represent like signals or elements described in FIG. 2.

The second VPP generator 1500 is supplied with a test external power supply voltage VEXT_REG through an N/C pin (not shown) and generates a high voltage VPP in response to a reference voltage VREFP. Hereinafter, an exemplary circuit configuration of the second VPP generator 1500 will be described in detail. Those internal voltage generators including a second VCORE generator 1500A and a second VCP generator 1500B illustrated in FIG. 2 have substantially the same circuit configuration as the second VPP generator 1500 illustrated in FIG. 3.

In more detail, the second VPP generator 1500 is controlled by a second enable signal VPDRVEN and, includes a comparison unit 1520, a driving unit 1540, and a dividing unit 1560. The comparison unit 1520 compares the reference voltage VREFP with a feedback voltage FB_VREFP. The driving unit 1540 executes a pull-up driving operation on the high voltage VPP in response to a comparison signal COMPS outputted from the comparison unit 1520. The dividing unit 1560 is controlled by the second enable signal VPDRVEN and divides the high voltage VPP to generate the feedback voltage FB_VREFP.

The driving unit 1540 includes a first P-type channel metal-oxide semiconductor (PMOS) transistor MP1 and a second PMOS transistor MP2. The first PMOS transistor MP1 has one terminal to which the test external power supply voltage VEXT_REG is supplied, the other terminal to which the high voltage VPP is supplied, and a gate to which the comparison signal COMPS is inputted. The second PMOS transistor MP2 controls a connection between the gate of the first PMOS transistor MP1 and the terminal of the test external power supply voltage VEXT_REG in response to the second enable signal VPDRVEN received at a gate of the second PMOS transistor MP2.

The dividing unit 1560 includes a diode structure DIODE_1 configured in a third PMOS transistor MP3, a first N-type channel metal-oxide semiconductor (NMOS) transistor MN1, a second NMOS transistor MN2, and a diode structure DIODE_2 configured in a fourth PMOS transistor MP4. The third PMOS transistor MP3, the first NMOS transistor MN1, the second NMOS transistor MN2, and the fourth PMOS transistor MP4 are coupled in series between a terminal of a ground voltage VSS and the other terminal of the first PMOS transistor MP1, i.e., an output terminal for the high voltage VPP. The first and second NMOS transistors MN1 and MN2 are controlled by the second enable signal VPDRVEN. The feedback voltage FB_VREFP is outputted through a node where the first NMOS transistor MN1 and the second NMOS transistor MN2 are commonly coupled to each other.

According to various embodiments of the present invention, various internal voltages are generated using the test external power supply voltage VEXT_REG through one N/C pin during a test mode for testing internal voltage operation circuits. In the test mode, the internal voltage operation circuits are tested using the internal voltages. For instance, in one embodiment, when the second VPP generator is used in the test mode in which the high voltage VPP is necessary, the test external power supply voltage VEXT_REG is supplied through one of the N/C pins to generate the high voltage VPP.

The DQ pad is used only to output the test results. Hence, an error which may occur when the test result data is not inputted can be checked since the DQ pad is not necessary for supplying the internal voltages. Also, during the normal mode, the second enable signal VPDRVEN is inactivated to a logic low state, causing the second VPP generator 1500 to turn off. As a result, unnecessary current dissipation does not occur. Furthermore, since only one of the N/C pins is used, the test results are reliable even if the number of internal voltage operation circuits increases.

The present application contains subject matter related to the Korean patent application Nos. KR 2005-090912 and 2006-0049115, filed in the Korean Patent Office respectively on Sep. 29, 2005, and on May 31, 2006, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims. For instance, the position and types of the transistors exemplified in the present embodiments can vary depending on a polarity of an inputted signal.

What is claimed is:

1. A semiconductor device comprising:
a first internal voltage generator generating an internal voltage using a first external power supply voltage in a normal mode;
a second internal voltage generator generating the internal voltage using a second external power supply voltage supplied through a no connection (N/C) pin in a test mode;
an internal operation circuit performing a target operation with the internal voltage generated at one of the first internal voltage generator and the second internal voltage generator; and
a data output buffer outputting an output data in response to the target operation by the internal operation circuit through a data input/output pad in one of the normal mode and the test mode.

2. The semiconductor device of claim 1, wherein the second external power supply voltage has a greater voltage level than the first external power supply voltage.

3. The semiconductor device of claim 1, wherein the first internal voltage generator operates in response to a first enable signal that is activated in the normal mode and inactivated in the test mode.

4. The semiconductor device of claim 3, wherein the second internal voltage generator operates in response to a second enable signal that is activated in the test mode and inactivated in the normal mode.

5. The semiconductor device of claim 4, wherein the second internal voltage generator comprises:
a comparison unit controlled by the second enable signal and comparing a predetermined reference voltage with a feedback voltage;
a driving unit pull up driving an internal voltage terminal in response to an output signal of the comparison unit; and
a dividing unit controlled by the second enable signal and dividing a voltage applied to the internal voltage terminal to be outputted as the feedback voltage.

6. The semiconductor device of claim 5, wherein the driving unit comprises:
a first P-type channel metal-oxide semiconductor (PMOS) transistor comprising a gate receiving an output signal of the comparison unit, the first PMOS transistor having one terminal coupled to a second external power supply voltage terminal and the other terminal coupled to the internal voltage terminal; and
a second PMOS transistor comprising a gate receiving the second enable signal, the second PMOS transistor having one terminal coupled to the second external power supply voltage terminal and the other terminal coupled to the gate of the first PMOS transistor.

7. The semiconductor device of claim 5, wherein the dividing unit comprises:
a third PMOS transistor configured in a diode structure;
a first N-type channel metal-oxide semiconductor (NMOS) transistor;
a second NMOS transistor; and
a fourth PMOS transistor configured in a diode structure, wherein the third PMOS transistor, the first and second NMOS transistors and the fourth PMOS transistor are coupled sequentially in series.

8. The semiconductor device of claim 7, wherein each of the first and second NMOS transistors comprises a gate receiving the second enable signal and outputs the feedback voltage through a node where the first and second NMOS transistors are commonly coupled to each other.

9. A driving method of a semiconductor device, the driving method comprising:
generating an internal voltage using a first external power supply voltage in a normal mode;
generating the internal voltage using a second external power supply voltage supplied through an N/C pin in a test mode;
performing a target operation after receiving the internal voltage; and
outputting an output data through a data input/output pad in one of the normal mode and the test mode.
